(19) United States
(12) Patent Application Publication
(10) Pub. No.: US 2004/0027137 A1
(43) Pub. Date: Feb. 12, 2004

(54) Time domain reflectometry probe for level sensing

(75) Inventor: Wayne Sherrard, Edmonton (CA)

Correspondence Address: MERCHANT & GOULD PC, P.O. BOX 2903, MINNEAPOLIS, MN, 55402-0903, US

(73) Assignee: Siemens Milltronics Process Instruments Inc., Peterborough (CA)

(21) Appl. No.: 10/426,165

(22) Filed: Apr. 29, 2003

(30) Foreign Application Priority Data
Apr. 29, 2002 (CA) 2,384,257

(51) Int. Cl. G01R 27/04; G01R 27/32

(52) U.S. Cl. 324/644

(57) ABSTRACT

A probe structure for sensing the level of a liquid or the interface between liquids contained in a vessel using Time Domain Reflectometry measurement technique. The probe comprises a conductive hollow rod and a conductive inner rod in a coaxially spaced relationship inside the hollow rod and extending along the length of the hollow rod. The hollow rod includes perforations along its length to maintain the same liquid level within the probe as that inside the vessel holding the liquid.

### FIELD OF THE INVENTION

The present invention relates to level sensing, and more particularly to a probe structure for use in time domain reflectometry (TDR) level sensing systems.

### BACKGROUND OF THE INVENTION

Probe structures based on the TDR technique have been widely used in a variety of liquid inventory and level sensing applications. In level sensing applications, a probe is immersed in a liquid contained in a storage vessel and used to convey incident pulses into the vessel and receive reflected signals generated by the impedance changes across the liquid interfaces. The time difference between an induced reference reflection and the interface surface is determined and used to perform level measurements or monitor other characteristic properties of the contained liquid.

Known TDR level sensing systems suffer from the loss of reflected pulses when measuring the level of liquids having low dielectric constants. In the prior art, there are TDR-based level measurement systems which employ advanced signal processing to improve detection of the reflected pulses. However, these systems are usually quite complex and not readily suitable to a variety of different level detection applications.

Prior TDR level detection systems are also limited in that, without resorting to complex signal processing, the liquid sensing device or the probe is unable to accurately measure the liquid or interface level in applications with fast changing levels.

In view of the foregoing, there remains a need for probe structures which improve the accuracy and performance of TDR-based level measurement systems.

### BRIEF SUMMARY OF THE INVENTION

The present invention provides a probe for sensing fluid level that is structurally simple and can be easily integrated in plurality level sensing applications. The present invention provides for improved reflected signal energy, making it suitable for low cost, faster response TDR level detector circuitry and firmware implementation.

The present invention arises from the realization that the loss of reflected energy while sensing the level of liquids with low dielectric constants can be significantly reduced by means of a novel TDR probe design having overlapping perforations or apertures along its length such that the liquid level inside the probe is equalized with the level outside the probe. The invention uses a probe design that improves the amount of reflected energy so that the interface level between liquids having low dielectric constants can be readily detected without resorting to complex TDR level detection and signal processing circuitry. The overlapping perforations or apertures along the length of the probe assure that the interface level is substantially the same along the length of the probe.

In a first aspect, the present invention provides a probe for use in the Time Domain Reflectometry (TDR) for sensing the level of a liquid contained in a vessel, the probe comprises: a conductive hollow rod having an interior area, the conductive hollow rod having at least a perforation to maintain the liquid at a same level within the interior area of the conductive hollow rod as exterior to the conductive hollow rod; and a conductive inner rod in spaced relationship with and coaxially extending through the conductive hollow rod for propagating a TDR pulse through the liquid.

In a second aspect, the present invention provides for a time domain reflectometry system, a probe for sensing the level of a liquid contained in a vessel, the probe comprises: a conductive rod adapted for mounting inside the vessel; and a hollow generally cylindrical conductive sheath in spaced relationship with the conductive rod, the conductive rod being located within the conductive sheath, the conductive sheath having at least a perforation along a portion of its length for allowing the liquid to pass into a cavity formed between the conductive sheath and the conductive rod, so as to maintain the same level of liquid inside and outside the conductive sheath.

In a further aspect, the present invention provides a level sensing system comprising: pulse generating means for generating an incident TDR pulse; transmission means for propagating the incident TDR pulse through a medium and receiving the corresponding reflected pulse at a level in the medium wherein a discontinuity in the dielectric constant of the medium occurs, the transmission means defining at least a perforation so as to maintain a same level of medium inside the transmission line means; means for detecting the reflected TDR pulse; and means for analyzing the reflected signal to ascertain the level.

Other aspects and features of the present invention will become apparent to those ordinarily skilled in the art upon review of the following description of specific embodiments of the invention in conjunction with the accompanying figures.

### BRIEF DESCRIPTION OF THE DRAWINGS

Reference will now be made to the accompanying drawings, which show, by way of example, embodiments of the present invention, and in which:

FIG. 1 is a schematic view of a TDR level sensing probe according to an embodiment of the present invention;

FIG. 2(a) is a sectional view of a TDR level sensing probe taken along the line A-A of FIG. 1;

FIG. 2(b) is an end view of the TDR level sensing probe of FIG. 1 and FIG. 2(a);

FIG. 3(a) is schematic view of a TDR level sensing probe according to an embodiment of the invention;

FIG. 3(b) is schematic view of a TDR level sensing probe according to another embodiment of the invention; and

FIG. 4 is schematic view of a TDR-based fluid level measurement system including a probe structure according to the present invention.

### DETAILED DESCRIPTION OF THE EMBODIMENTS

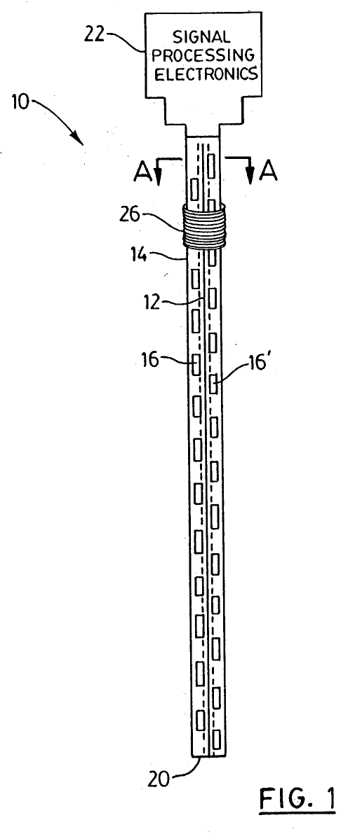

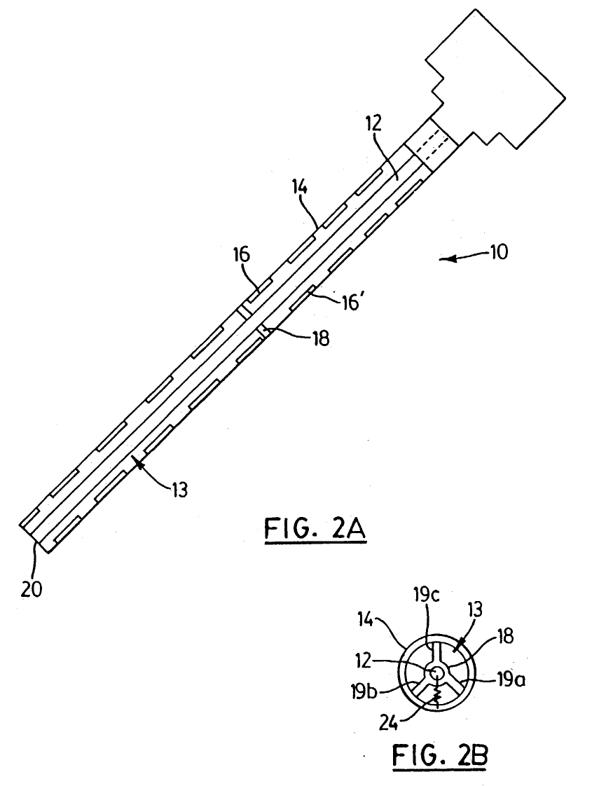

Reference is made to FIGS. 1, 2(a) and 2(b) which show a liquid level sensing probe 10 for sensing the level of a contained liquid or determining the interface levels between two or more liquids in a TDR-based measurement system. As shown in FIGS. 1 and 2(a), the liquid level sensing probe 10 includes an inner conducting rod 12 (FIG. 2(a)) formed from stainless steel, copper or other electrically conductive material in spaced relationship with an open-ended electrically conductive hollow rod 14. The hollow rod 14 is coaxially arranged with the inner rod 12 and is made of stainless steel, copper or other electrically conductive material. Together, the inner rod 12 and the hollow rod 14 comprise a transmission line which is used for detecting the level of a liquid or the interface between liquids present inside an annular cavity indicated by reference 13 in FIGS. 2(a) and 2(b) formed by the area between the inner wall of the hollow rod 14 and the outside surface of the inner rod 12.

The hollow rod 14 includes an open end 20 to permit liquid to rise within the cavity between the inner rod 12 and the hollow rod 14. In addition, the hollow rod 14 includes overlapping perforations or slots 16, 16′ along its length to regulate the flow of liquid filling the cavity between the inner rod 12 and the hollow rod 14. As the liquid penetrates inside the hollow rod 14, the material (such as air, gas, etc.) in the hollow rod 14 escapes through the overlapping perforations 16, 16′ and is quickly replaced by the rising liquid.

As shown in FIG. 1, TDR signal processing electronics 22 are operatively coupled to one end of the probe 10 for launching incident pulses along the length of the probe 10. The TDR signal processing electronics 22 may comprise a pulse generator (not shown) and signal processing modules (not shown) such as A/D converters and a suitably programmed microcontroller or microprocessor as will be within the understanding of one skilled in the art.

The TDR signal processing electronics 22 are responsive to the changes in the reflected energy when the incident pulses traveling along the probe 10 encounter a discontinuity in the medium, such as a change in the dielectric constant at the interface between two liquids. This discontinuity causes a reflection of the incident pulse along the probe 10 at the point of discontinuity. The time difference between the reflection relative to the time of the incident pulse is then used to determine the location of the discontinuity.

The probe 10 may be threadably fastened to the hollow rod 14 by means of a threaded fastener or the like (not shown). Alternatively, the inner rod 12 may be welded to the hollow rod 14 in order to firmly secure the inner rod 12 inside the hollow rod 14.

The exposed sensing surface areas of the inner rod 12 and the hollow rod 14 maybe coated by a layer of insulating material such as TEFLON™, PEEK™ or NYLON™ to prevent the TDR signal from dissipating when traveling along the length of the probe 10.

As shown in FIG. 2(b), the probe 10 may also include a spacer 18 to maintain a constant radial distance between the hollow rod 14 and the inner rod 12. The spacer 18 is attached to the inner rod 12 (for example snap-fitted) and includes a plurality of radially extending legs 19a, 19b, 19c adapted to receive the inner wall of the hollow rod 14 to maintain the same spaced relationship between the inner rod 12 and the hollow rod 14 along the length of the probe 10. The spacer 18 is typically made of a plastic polymer, such as TEFLON™, PEEK™, NYLON™ or other similar non-conducting material. Where the inner rod 12 and the hollow rod 14 are required to be electrically coupled together, the spacer 18 may be made of conducting material such as stainless steel, copper, silver, aluminum, or other similar conducting material. In applications were the length of the probe 10 is considerably long, more than one of the spacers 18 may be employed in order to retain the hollow rod 14 substantially concentric with the inner rod 12. As shown in FIG. 2(b), the inner rod 12 is electrically coupled to the probe 14 by means of a terminating resistor 24 to match the characteristic impedance of the probe with that of the TDR signal processing electronics. Alternatively, a thin cross bar (not shown) having an electrical resistance equal to the characteristic impedance of the inner rod 12 may be attached at one end to the inner rod 12 and at the other end to the inner side of the hollow rod 14 in order to firmly support the inner rod 12 within the hollow rod 14.

The probe structure 10 is adapted to be mounted on the wall of a vessel by a threaded mount, clamp or the like, indicated generally by reference 26 in FIG. 1. Anchoring the probe 10 to the vessel may be necessary in instances where the length of the probe 10 is excessively long in order to provide further support for the probe 10 and to prevent vibration or fluid movement affecting the functioning of the probe 10.

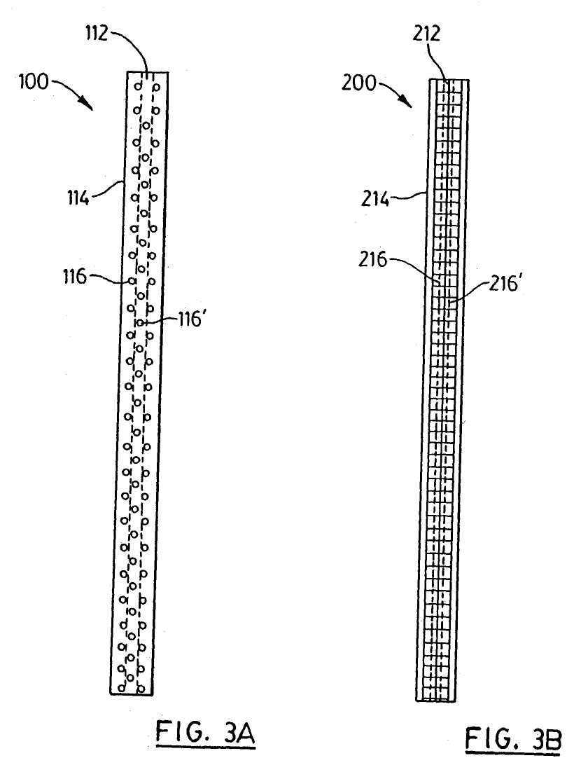

Reference is next made to FIGS. 3(a) and 3(b), which show alternate embodiments of the probe structure for use in level measurement of liquids with specific consistency. FIG. 3(a) shows a TDR-based level sensing probe 100 which includes a transmission line formed by a conductive inner rod 112 coaxially arranged within a conductive hollow rod 114. A number of apertures or openings 116, 116′ are provided along the length of the hollow rod 114. The apertures 116, 116′ not only permit maintaining the same level of liquid inside the probe 100 as opposed to outside of the probe 100, but also act as a sieve for filtering debris or particles inside the liquid. By adjusting the the diameter of the apertures 116 and/or 116′, it becomes possible to selectively block or prevent the flow of particles of a certain size or shape into the probe 100.

FIG. 3(b) shows a probe structure 200 having a conductive inner rod 212 coaxially arranged within conductive hollow rod 214, wherein a plurality of longitudinally extending slots 216, 216′ are formed on the wall of the hollow rod 214. The slots 216, 216′ serve to equalize the liquid level inside of the probe 200 as compared to outside of the probe 200.

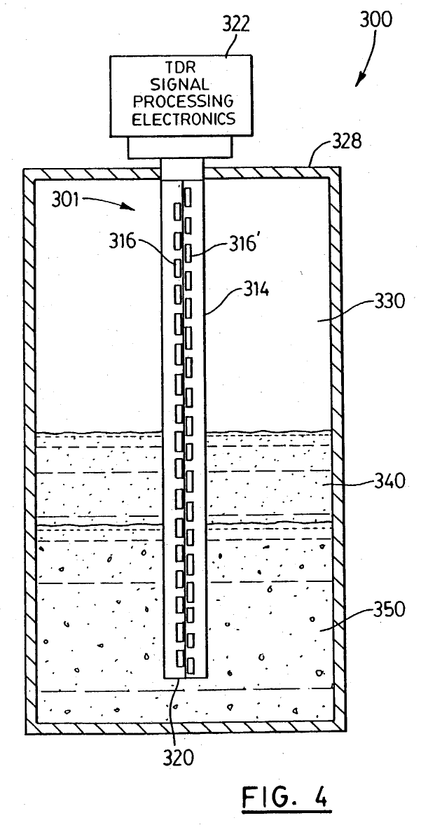

Reference is next made to FIG. 4 which shows a TDR-based fluid level measurement system 300 including a probe structure 301 in accordance With the present invention for detecting the interface between liquids 350, 360. The probe 301 is mounted in a vessel 328 such as a storage tank, decantation column, or a liquid-filled receptacle, and includes a conductive inner rod 12 as shown in FIG. 2(a) coaxially extending within a generally hollow conductive rod 314. The conductive inner rod 12 and the hollow rod 314 comprise a low quality transmission line which may used to detect the interfaces between the liquids 350, 360 using TDR techniques. The probe structure 301 extends within the vessel to allow the probe 301 to come into contact with a bottom liquid 350 and a top liquid 340.

As shown, a plurality of overlapping perforations 316, 316′ are provided substantially along the length of the probe 301. As a result, the probe 301 is surrounded and filled by the liquids 350, 360 contained in the vessel 328. As the level of liquids 350, 360 changes insides the vessel 328, the overlapping perforations 316, 316′ allow the liquid inside the probe 301 to be quickly replaced by air 330 in the vessel 328, such that the liquid level inside the probe 301 rigorously follows the liquid level outside the probe 301.

The measurement system 300 shown in FIG. 4 also includes TDR signal processing electronics 322 connected to the probe 301 for performing TDR level monitoring. The TDR signal processing electronics 322 may be disposed on top wall (or the sidewall) of the vessel 328. In operation, the TDR signal processing electronics 322 launches an incident pulse along the probe 301 and extending over the range of liquid levels being detected. When the liquid level inside the probe 301 rises to a level at which the liquids 350, 360 are contained inside the probe 301, the interfaces between the liquids 350, 360 produce impedance changes as a result of different dielectric constants of the contained liquids 350, 360. The change in the impedance in turn causes an amplitude and phase shift in the reflected pulse. This amplitude and phase shift is detected by the TDR signal processing electronics 322 and used to determine the current location of the the interface between the liquids 350, 360.

The present invention may be embodied in other specific forms without departing from the spirit or essential characteristics thereof. Certain adaptations and modifications of the invention will be obvious to those skilled in the art. Therefore, the presently discussed embodiments are considered to be illustrative and not restrictive, the scope of the invention being indicated by the appended claims rather than the foregoing description, and all changes which come within the meaning and range of equivalency of the claims are therefore intended to be embraced therein.

What is claimed is:

1. A probe for use in the Time Domain Reflectometry (TDR) for sensing the level of a liquid contained in a vessel, the probe comprising:
a conductive hollow rod having an interior area, the conductive hollow rod having at least a perforation to maintain the liquid at a same level within the interior area of the conductive hollow rod as exterior to the conductive hollow rod; and
a conductive inner rod in spaced relationship with and coaxially extending through the conductive hollow rod for propagating a TDR pulse through the liquid.

2. The probe as claimed in claim 1, wherein the perforations in the conductive hollow rod are overlapping.

3. The probe as claimed in claim 2, wherein the perforations in the conductive hollow rod are equidistance.

4. The probe as claimed in claim 3, wherein the conductive hollow rod and the conductive inner rod comprise a conductive metal selected from the group consisting of stainless steel and copper.

5. The probe as claimed in claim 1, wherein the conductive hollow rod and the conductive inner rod are in a parallel spaced relationship.

6. The probe as claimed in claim 5, wherein the conductive inner rod extends substantially along the length of the conductive hollow rod.

7. The probe as claimed in claim 6, wherein the conductive inner rod is electrically coupled to the conductive hollow rod by a terminating resistor.

8. The probe as claimed in claim 7, wherein the conductive inner rod is electrically coupled to the conductive hollow rod by a thin cross bar having a same characteristic impedance as the inner conductive rod.

9. The probe as claimed in claim 1 further comprising means for securing the conductive inner rod inside the hollow rod.

10. The probe as claimed in claim 1 further comprising at least a spacer coupled to the conductive inner rod for maintaining a spaced relationship between the conductive inner rod and the conductive hollow rod.

11. The probe as claimed in claim 10, further comprising means for attaching the spacers to the conductive inner rod.

12. The probe as claimed in claim 11, wherein the spacer is made of non-conducting material selected from the group consisting of TEFLON™, PEEK™ and NYLON™.

13. The probe as claimed in claim 11, wherein the spacer comprises a conductive material selected from the group consisting of stainless steel, copper, silver and aluminum.

14. The probe as claimed in claim 1, wherein the conductive hollow rod defines an opening at a distal end to allow liquid rise within the inside area of the conductive hollow rod.

15. In a time domain reflectometry system, a probe for sensing the level of a liquid contained in a vessel, the probe comprising:
a conductive rod adapted for mounting inside the vessel; and
a hollow generally cylindrical conductive sheath in spaced relationship with the conductive rod, the conductive rod being located within the conductive sheath, the conductive sheath having at least a perforation along a portion of its length for allowing the liquid to pass into a cavity formed between the conductive sheath and the conductive rod, so as to maintain the same level of liquid inside and outside the conductive sheath.

16. The probe as claimed in claim 15, wherein the conductive rod is generally centrally located with respect to the conductive sheath.

17. The probe as claimed in claim 16 further comprising means for maintaining a constant radial distance between the conductive rod and the conductive sheath.

18. The probe as claimed in claim 17, wherein the means for maintaining a constant radial distance includes at least an aperture to permit unobstructed rising or falling level of liquid in the vessel.

19. A level sensing system comprising:
pulse generating means for generating an incident TDR pulse;
transmission means for propagating the incident TDR pulse through a medium and receiving the corresponding reflected pulse at a level in the medium wherein a discontinuity in the dielectric constant of the medium occurs, the transmission means defining at least one perforation so as to maintain a same level of medium inside the transmission line means;
means for detecting the reflected TDR pulse; and
means for analyzing the reflected signal to ascertain the level.

20. The level sensing system as claimed in claim 19, wherein the transmission line includes a plurality of perforations.

21. The level sensing system as claimed in claim 20, wherein the perforations comprise an overlapping arrangement.
